(19) United States
(12) Patent Application Publication
(10) Pub. No.: US 2026/0209928 A1
(43) Pub. Date: Jul. 23, 2026

(54) DEPOSITION MASK, METHOD OF MANUFACTURING DEPOSITION MASK, AND APPARATUS FOR MANUFACTURING DISPLAY PANEL

(71) Applicant: SAMSUNG DISPLAY CO., LTD., YONGIN-SI (KR)

(72) Inventors: Jeongkuk Kim, YONGIN-SI (KR); Subin Bae, YONGIN-SI (KR); Jihyun Jung, YONGIN-SI (KR); Sungwon Cho, YONGIN-SI (KR)

(21) Appl. No.: 19/315,923

(22) Filed: Sep. 2, 2025

(30) Foreign Application Priority Data
Jan. 21, 2025 (KR) 10-2025-0008856

(51) Int. Cl. C23C 14/04

(52) U.S. Cl. CPC C23C 14/042

(57) ABSTRACT

A deposition mask includes a mask frame including a plurality of cell areas arranged to be spaced apart from each other in a plan view and a protrusion disposed between the plurality of cell areas in the plan view. A mask membrane is disposed on the mask frame and includes a crack overlapping the protrusion.

### CROSS-REFERENCE TO RELATED APPLICATION

This application claims priority under 35 U.S.C. § 119 to Korean Patent Application No. 10-2025-0008856, filed on Jan. 21, 2025 in the Korean Intellectual Property Office, the disclosure of which is incorporated by reference in its entirety herein.

### 1. Technical Field

One or more embodiments relate to a deposition mask. One or more embodiments relate to a method of manufacturing a deposition mask. One or more embodiments relate to an apparatus for manufacturing a display panel, the apparatus including a deposition mask.

### 2. Discussion of Related Art

Various electronic devices include display panels for displaying a variety of subject matter. Display panels may provide images by using light-emitting diodes. The uses and structures of display panels have become more diverse along with the advancement of the information society. Additionally, display panels that may be bent or otherwise deformed from a flat state to have a certain angle have also been developed for increased user convenience. Recently, various designs have been attempted to increase the quality of display panels.

A display panel may include a plurality of pixels arranged in a pattern to provide at least one moving and/or still image. In this case, several layers including an emission layer may be included in the plurality of pixels arranged in the pattern. The several layers may be arranged on a substrate in different patterns according to their types. In a process for manufacturing a display panel, each layer of a display panel may be formed by depositing a deposition material using a deposition mask having an opening corresponding to a pattern to be formed on a substrate. The deposition mask may include a mask membrane including an opening defining a deposition area corresponding to the pattern and a mask frame to which the mask membrane is fixed. In a process of manufacturing a mask, a crack may occur in the mask membrane due to stress formed on the mask membrane. Therefore, research is being conducting concerning a structure capable of preventing such a crack from occurring in an area where the opening of the mask membrane defining the deposition area is disposed which results in defects in the manufacturing process.

### SUMMARY

According to an embodiment of the present disclosure, a mask frame comprising a plurality of cell areas arranged to be spaced apart from each other in a plan view and a protrusion disposed between the plurality of cell areas in the plan view. A mask membrane is disposed on the mask frame and includes a crack overlapping the protrusion.

In an embodiment, the protrusion may include a first portion extending in a first direction and a second portion extending in a second direction intersecting the first direction.

In an embodiment, the protrusion may be disposed between a corner of one of the plurality of cell areas and a corner of another of the plurality of cell areas in the plan view.

In an embodiment, the protrusion may be provided in a mesh shape at least partially surrounding the plurality of cell areas in the plan view.

In an embodiment, the protrusion may have a width that decreases in a protruding direction in a cross-sectional view.

In an embodiment, a width of a tip of the protrusion may be less than or equal to about 0.1 nanometers.

In an embodiment, the crack of the mask membrane may include a first crack extending in a first direction and a second crack extending in a second direction intersecting the first direction and may be defined in a mesh shape at least partially surrounding the plurality of cell areas in the plan view.

In an embodiment, the mask membrane may be separated into a plurality of islands in the plan view by the crack.

In an embodiment, the mask membrane includes a groove disposed between the protrusion and the plurality of cell areas in the plan view.

In an embodiment, the mask frame includes a plurality of first openings corresponding to the plurality of cell areas, and the mask membrane includes a plurality of second openings overlapping the plurality of first openings and defining a deposition area.

According to an embodiment of the present disclosure, a method of manufacturing a deposition mask includes forming, on a mask frame substrate including a plurality of cell areas arranged to be spaced apart from each other in a plan view, a protrusion between the plurality of cell areas in the plan view, and disposing a mask membrane substrate on the mask frame substrate to form a crack overlapping the protrusion.

In an embodiment, the protrusion may be disposed between a corner of one of the plurality of cell areas and a corner of another of the plurality of cell areas in the plan view.

In an embodiment, the protrusion may be provided in a mesh shape at least partially surrounding the plurality of cell areas in the plan view.

In an embodiment, in a cross-sectional view, the protrusion may have a width that decreases in a protruding direction, and the crack may overlap a tip of the protrusion.

In an embodiment, the forming of the protrusion may include etching the mask frame substrate.

In an embodiment, the protrusion may include a different material from the mask frame substrate.

In an embodiment, the crack may include a first crack extending in a first direction and a second crack extending in a second direction intersecting the first direction, the crack may be defined in a mesh shape at least partially surrounding the plurality of cell areas in the plan view, and the mask membrane substrate may be separated into a plurality of islands in the plan view by the crack.

In an embodiment, the method may further include forming, in the mask membrane substrate, a groove disposed between the crack and the plurality of cell areas in the plan view.

In an embodiment, the method may further include forming a plurality of first openings corresponding to the plurality of cell areas in the mask frame substrate, and forming a plurality of second openings overlapping the plurality of first openings and defining a deposition area in the mask membrane substrate.

According to an embodiment of the present disclosure, an apparatus for manufacturing a display panel includes a chamber, a deposition mask disposed in the chamber, and a deposition source disposed in the chamber to face the deposition mask. The deposition mask includes a mask frame including a plurality of cell areas arranged to be spaced apart from each other in a plan view and a protrusion disposed between the plurality of cell areas in the plan view, and a mask membrane disposed on the mask frame and including a crack overlapping the protrusion.

### BRIEF DESCRIPTION OF THE DRAWINGS

The above and other aspects, features, and advantages of certain non-limiting embodiments will be more apparent from the following description taken in conjunction with the accompanying drawings, in which:

FIG. 1 is a cross-sectional view illustrating an apparatus for manufacturing a display panel, according to an embodiment of the present disclosure;

FIG. 2 is a plan view illustrating a mask frame, according to an embodiment of the present disclosure;

FIG. 3 is a cross-sectional view illustrating the mask frame, taken along line II-II′ of FIG. 2 according to an embodiment of the present disclosure;

FIG. 4 is a plan view illustrating a deposition mask, according to an embodiment of the present disclosure;

FIG. 5 is a cross-sectional view illustrating a deposition mask, according to an embodiment of the present disclosure;

FIG. 6 is a cross-sectional view illustrating a deposition mask, according to an embodiment of the present disclosure;

FIG. 7 is a plan view illustrating a mask frame, according to an embodiment of the present disclosure;

FIG. 8 is a cross-sectional view illustrating the mask frame, taken along line VII-VII′ of FIG. 7 according to an embodiment of the present disclosure;

FIG. 9 is a plan view illustrating a deposition mask, according to an embodiment of the present disclosure;

FIG. 10 is a cross-sectional view illustrating a deposition mask, according to an embodiment of the present disclosure;

FIG. 11 is a cross-sectional view illustrating a deposition mask, according to an embodiment of the present disclosure;

FIGS. 12A, 12B, 12C, 12D, 12E, and 12F are cross-sectional views illustrating processes of a method of manufacturing a deposition mask, according to embodiments of the present disclosure;

FIG. 13 is a block diagram illustrating an electronic device, according to an embodiment of the present disclosure;

FIGS. 14, 15, and 16 are schematic views illustrating an electronic device, according to various embodiments of the present disclosure;

FIG. 17 is a schematic plan view illustrating an electronic device, according to an embodiment of the present disclosure; and

FIG. 18 is a cross-sectional view illustrating a display panel, according to an embodiment of the present disclosure.

### DETAILED DESCRIPTION OF EMBODIMENTS

Reference will now be made in detail to non-limiting embodiments, examples of which are illustrated in the accompanying drawings, wherein like reference numerals refer to like elements throughout. In this regard, the present embodiments may have different forms and should not be construed as being limited to the descriptions set forth herein. Accordingly, non-limiting embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the present disclosure, and methods for achieving them will be clarified with reference to non-limiting embodiments described below in detail with reference to the drawings. However, embodiment of the present disclosure are not limited to the following described embodiments and may be embodied in various forms.

Hereinafter, embodiments will be described in detail with reference to the accompanying drawings, wherein the same or corresponding elements are denoted by the same reference numerals throughout and a repeated description thereof is omitted. Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on,” “above,” “under,” and “below” another layer, region, or component, it may be directly on the other layer, region, or component, or intervening layers, regions, or components may be present.

Sizes of components in the drawings may be exaggerated or reduced for convenience of explanation. For example, because sizes and thicknesses of components in the drawings may be arbitrarily illustrated for convenience of explanation, embodiments of the present disclosure are not necessarily limited thereto.

In the following embodiments, a first direction DR1, a second direction DR2, and a third direction DR3 are not necessarily limited to three directions in the orthogonal coordinate system, and may be interpreted in a broader sense. For example, the first direction DR1, the second direction DR2, and the third direction DR3 may be orthogonal to each other, or may represent different directions that are not orthogonal to each other and may intersect each other at various different angles.

When a certain embodiment may be implemented differently, a specific process order may be different from the described order. For example, two consecutively described processes may be performed substantially at the same time or may be performed in an order opposite to the described order.

The present disclosure concerns a deposition mask that includes a mask membrane having a crack formed solely between cell areas of the mask frame where deposition using the deposition mask occurs. The mask frame includes protrusions overlapping the crack. The crack is guided by the positioning of the protrusions to be solely formed between the cell areas. Therefore, a crack may be prevented or reduced from occurring in the cell area and stress applied to the mask membrane in the cell area may be reduced. Accordingly, the deposition process using the deposition mask may have increased accuracy.

A groove may be disposed between the cell area and the protrusion in a plan view. The groove separates a part of the mask membrane disposed on the protrusion from a part of the mask membrane where the deposition area is defined. Therefore, warpage of the mask membrane may be reduced or prevented.

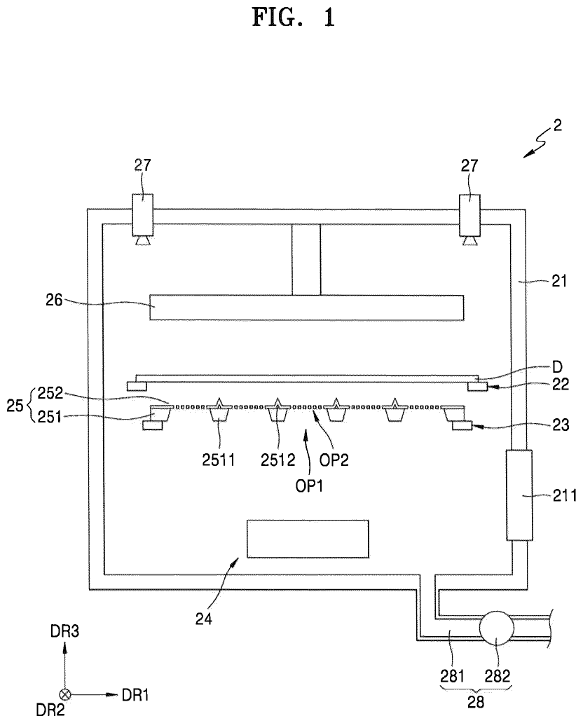

FIG. 1 is a cross-sectional view illustrating an apparatus for manufacturing a display panel, according to an embodiment.

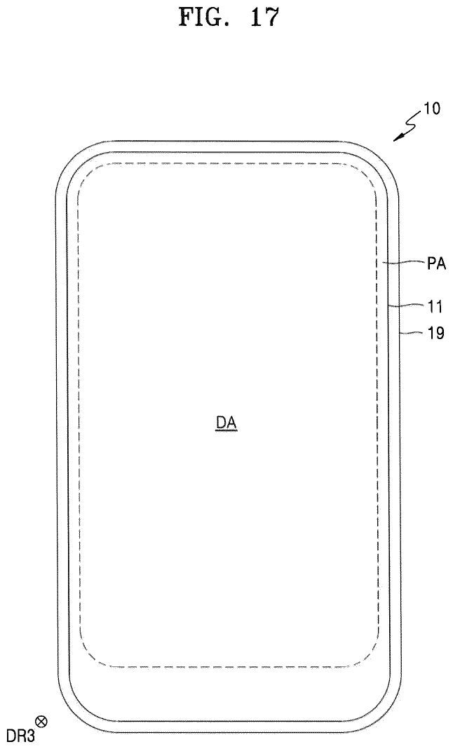

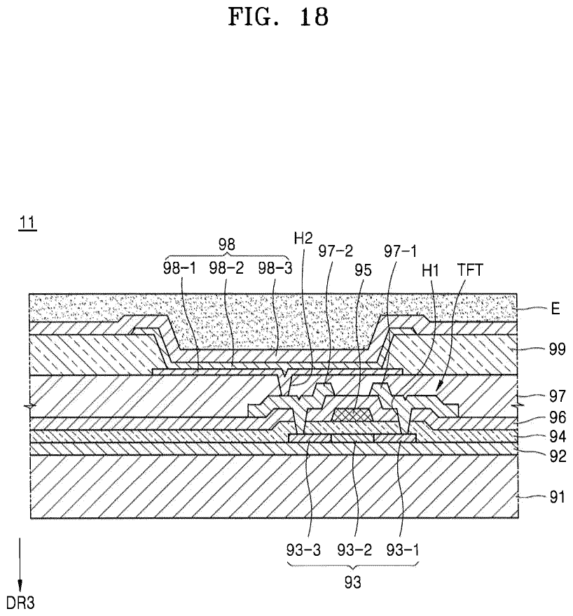

Referring to FIG. 1, in an embodiment an apparatus 2 for manufacturing a display panel may include a chamber 21, a first support 22, a second support 23, a deposition source 24, a deposition mask 25, a magnetic force unit 26, a vision unit 27, and a pressure adjusting unit 28. In an embodiment, the apparatus 2 for manufacturing a display panel may be a deposition device. An object to be processed D in the specification is a processing target of the apparatus 2 for manufacturing a display panel, and may be a semi-finished product of a display panel 11 (see FIGS. 17 and 18). For example, the object to be processed D may be a semi-finished product in which up to an arbitrary layer among layers included in the display panel 11 is formed. In an embodiment, the object to be processed D may correspond to a plurality of display panels 11. For example, the plurality of display panels 11 may be manufactured from one object to be processed D. Some of components of the apparatus 2 for manufacturing a display panel illustrated in FIG. 1 may be omitted, or the apparatus 2 for manufacturing a display panel may further include components other than the components illustrated in FIG. 1.

A space may be formed in the chamber 21, and a portion of the chamber 21 may be open. In an embodiment, a gate valve 211 may be provided at the open portion of the chamber 21. In this embodiment, the open portion of the chamber 21 may be opened or closed according to an operation of the gate valve 211.

The first support 22 may support the object to be processed D seated on the first support 22. In an embodiment, the first support 22 may be a frame-type support fixed inside the chamber 21. In an embodiment, the first support 22 may be a shuttle-type support on which the object to be processed D is seated and that is linearly movable inside the chamber 21. In an embodiment, the first support 22 may include an electrostatic chuck or an adhesive chuck fixed to the chamber 21 or disposed in the chamber 21 to be lifted or lowered inside the chamber 21. For convenience of explanation, the following will be described assuming that the first support 22 is a frame-type support fixed inside the chamber 21.

The deposition mask 25 may be seated on (e.g., disposed directly thereon) the second support 23. In an embodiment, the second support 23 may be disposed inside the chamber 21. The second support portion 23 may finely adjust a position of the deposition mask 25. In an embodiment, the second support 23 may include a separate driver or alignment unit to move the deposition mask 25 in different directions. In an embodiment, the second support 23 may be a shuttle-type support. In an embodiment, the second support 23 may allow the deposition mask 25 to be seated thereon and may transport the deposition mask 25. For example, the second support 23 may move to the outside of the chamber 21 (e.g., the external environment), may allow the deposition mask 25 to be seated thereon (e.g., disposed directly thereon), and may enter the chamber 21 from the outside of the chamber 21.

In an embodiment, the first support 22 and the second support 23 may be integrally formed with each other. In this embodiment, the first support 22 and the second support 23 may each include a movable shuttle. In this case, the first support 22 and the second support 23 may include a structure for fixing the deposition mask 25 and the object to be processed D in a state where the object to be processed D is seated on the deposition mask 25, and may linearly move the object to be processed D and the deposition mask 25 at the same time.

For convenience of explanation, the following will be described assuming that the first support 22 and the second support 23 are distinguishably formed and disposed at different positions in the chamber 21.

The deposition source 24 may face the deposition mask 25 (e.g., in the third direction DR3). In an embodiment, a deposition material may be accommodated in the deposition source 24, and the deposition material may be evaporated or sublimated by applying heat to the deposition material. In an embodiment, the deposition source 24 may be disposed to be fixed in the chamber 21 or may be disposed inside the chamber 21 to be linearly movable along one direction. For convenience of explanation, the following will be described in detail assuming that the deposition source 24 is fixed inside the chamber 21.

The deposition mask 25 may include a mask frame 251 and a mask membrane 252. In an embodiment, the mask frame 251 may include a main body 2511 and a protrusion 2512. The protrusion 2512 may be disposed on the main body 2511. For example, in an embodiment the protrusion 2512 may be disposed on (e.g., directly thereon) the main body 2511 in the third direction DR3. In an embodiment, the protrusion 2512 may be integral with the main body 2511. A first opening OP1 may be defined in the mask frame 251. In an embodiment, the first opening OP1 may be defined in the main body 2511 of the mask frame 251. In an embodiment, a plurality of first openings OP1 may be provided, and the protrusion 2512 of the mask frame 251 may be disposed between the plurality of first openings OP1 (e.g., in the first direction DR1). The mask membrane 252 may be disposed on (e.g., directly thereon) the mask frame 251, for example, on the mask frame 251 in the third direction DR3. A second opening OP2 may be defined in the mask membrane 252. In an embodiment, a plurality of second openings OP2 may be provided in the mask membrane 252, and may define a deposition area of the deposition mask 25. The deposition area may refer to an area (or pattern) where the deposition material sprayed from the deposition source 24 is disposed on the object to be processed D. The second opening OP2 may be provided to correspond to a pattern for depositing the deposition material on the object to be processed D.

The magnetic force unit 26 may be disposed in the chamber 21 to face the object to be processed D. In an embodiment, the magnetic force unit 26 may pull the deposition mask 25 to the object to be processed D (e.g., towards the object to be processed D in the third direction DR3) by applying a magnetic force (e.g., an attractive force) to the deposition mask 25 (e.g., the mask membrane 252). The magnetic force unit 26 may not only prevent warpage of the mask membrane 252 but may also bring the mask membrane 252 into close contact with the object to be processed D. In an embodiment, the magnetic force unit 26 may uniformly maintain an interval between the mask membrane 252 and the object to be processed D along a longitudinal direction of the mask membrane 252 (e.g., the first direction DR1 or the second direction DR2).

The vision unit 27 may be provided in the chamber 21, and may photograph positions of the object to be processed D and the deposition mask 25. In an embodiment, the vision unit 27 may include a camera for photographing the object to be processed D and the deposition mask 25. Positions of the object to be processed D and the deposition mask 25 may be determined based on an image captured by the vision unit 27, and a position of the object to be processed D on the first support 22 may be finely adjusted or a position of the deposition mask 25 on the second support 23 may be finely adjusted based on the image.

The pressure adjusting unit 28 may be connected to the chamber 21 to adjust pressure in the chamber 21. For example, in an embodiment the pressure adjusting unit 28 may adjust pressure in the chamber 21 to be equal or similar to atmospheric pressure. Also, the pressure adjusting unit 28 may adjust pressure in the chamber 21 to be equal or similar to a vacuum state.

In an embodiment, the pressure adjusting unit 28 may include a connection pipe 281 connected to the chamber 21 and a pump 282 provided in the connection pipe 281. In this case, according to an operation of the pump 282, external air may be introduced through the connection pipe 281, or gas in the chamber 21 may be guided to the outside (e.g., the external environment) through the connection pipe 281.

In an embodiment, the apparatus 2 for manufacturing a display panel may be used to manufacture a display panel by operating through a process described below. First, when the pressure adjusting unit 28 maintains pressure in the chamber 21 to be equal or similar to atmospheric pressure, the gate valve 211 may operate to open the open portion of the chamber 21.

In an embodiment, the object to be processed D may then be loaded into the chamber 21 from the outside of the chamber 21. In this case, the object to be processed D may be loaded into the chamber 21 in various ways. In an embodiment, the object to be processed D may be loaded into the chamber 21 from the outside of the chamber 21 through a robot arm or the like disposed outside the chamber 21. In an embodiment, when the first support 22 is a shuttle-type support, the first support 22 may be carried from the chamber 21 to the outside of the chamber 21, and then, the object to be processed D may be seated on the first support 22 through the robot arm or the like disposed outside the chamber 21 and the first support 22 may be loaded from the outside of the chamber 21 into the chamber 21. For convenience of explanation, the following will be described in detail assuming that the object to be processed D is loaded into the chamber 21 from the outside of the chamber 21 through the robot arm disposed outside the chamber 21.

The deposition mask 25 may be disposed in the chamber 21 as described above. In an embodiment, the deposition mask 25 may be loaded into the chamber 21 from the outside of the chamber 21, in the same or similar manner as or to the object to be processed D. In an embodiment, the first support 22 and the second support 23 may include a shuttle, and the object to be processed D and the deposition mask 25 may be fixed to the shuttle and loaded into the chamber 21 from the outside of the chamber 21. For convenience of explanation, the following will be described in detail assuming that, in a state where the deposition mask 25 is disposed in the chamber 21, only the object to be processed D is loaded into the chamber 21 from the outside of the chamber 21.

When the object to be processed D is loaded into the chamber 21, the object to be processed D may be seated on (e.g., disposed directly thereon) the first support 22. The vision unit 27 may photograph positions of the object to be processed D and the deposition mask 25. In an embodiment, the vision unit 27 may photograph a first alignment mark of the object to be processed D and a second alignment mark of the deposition mask 25.

Positions of the object to be processed D and the deposition mask 25 may be determined based on the photographed first alignment mark and second alignment mark. In an embodiment, the apparatus 2 for manufacturing a display panel may include a separate controller to determine positions of the object to be processed D and the deposition mask 25. When positions of the object to be processed D and the deposition mask 25 are determined, the second support 23 may finely adjust the position of the deposition mask 25. Alternatively, the first support 22 may finely adjust the position of the object to be processed D. Accordingly, the object to be processed D and the deposition mask 25 may be aligned with each other.

After the object to be processed D and the deposition mask 25 are aligned, the object to be processed D and the deposition mask 25 may be brought into close contact with each other. In an embodiment, the object to be processed D, the deposition mask 25, and the magnetic force unit 26 may be brought into close proximity with each other. In an embodiment, the object to be processed D may not move, the deposition mask 25 may move towards the object to be processed D (e.g., in the third direction DR3), and the magnetic force unit 26 may move towards the object to be processed D (e.g., in a direction opposite to the third direction DR3). In an embodiment, the deposition mask 25 may not move, and the object to be processed D and the magnetic force unit 26 may move towards the deposition mask 25 (e.g., in the direction opposite to the third direction DR3). In an embodiment, the magnetic force unit 26 may pull the deposition mask 25 towards the object to be processed D (e.g., in the third direction DR3) by applying a magnetic force (e.g., an attractive force) to the deposition mask 25. In an embodiment, the deposition mask 25, for example, the mask membrane 252, may be in close contact with the object to be processed D. For example, the mask membrane 252 may be in close contact with a surface of the deposition mask 25 in the direction opposite to the third direction DR3.

Next, the deposition source 24 may operate to spray the deposition material to the deposition mask 25 (e.g., in the third direction DR3). The deposition material passing through the plurality of second openings OP2 of the mask membrane 252 may be deposited on the object to be processed D. In this case, the pump 282 may maintain pressure in the chamber 21 to be equal or similar to a vacuum state by sucking gas in the chamber 21 and discharging the gas to the outside (e.g., the external environment). The deposition material passing through the second openings OP2 of the mask membrane 252 and deposited on the object to be processed D may have substantially the same shape (or pattern) as the second openings OP2. The second openings OP2 of the mask membrane 252 may be formed to correspond to a designed deposition area and may provide a deposition area that is the same as or similar to the designed deposition area.

The above operation may be repeatedly performed on a plurality of objects to be processed D. In this case, the number of depositions for the plurality of objects to be processed D is the same as a preset number of times, the operation of the apparatus 2 for manufacturing a display panel may be stopped and the deposition mask 25 may be taken out of the chamber 21. Next, a new deposition mask 25 may be loaded into the chamber 21 and the above process may be repeated.

Through the above process, the apparatus 2 for manufacturing a display panel may deposit a deposition material on an area that is the same as or similar to a designed shape on the object to be processed D. Also, because the apparatus 2 for manufacturing a display panel may deposit a deposition material in a precise pattern, a display panel that may provide a precise image may be manufactured.

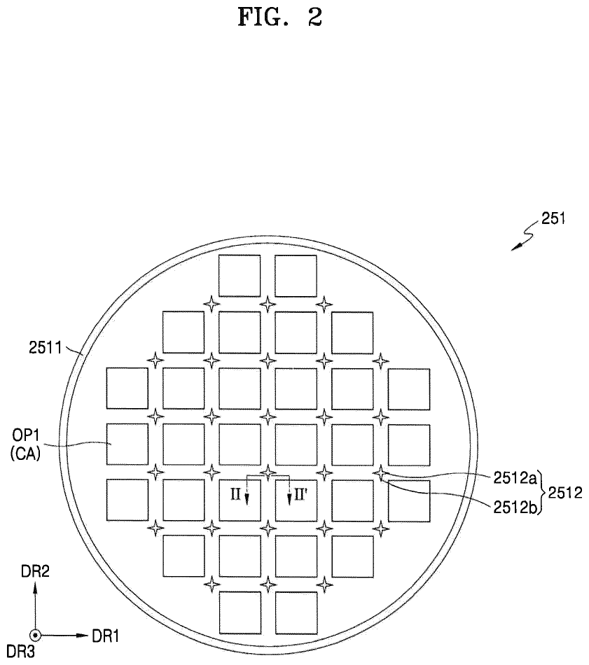

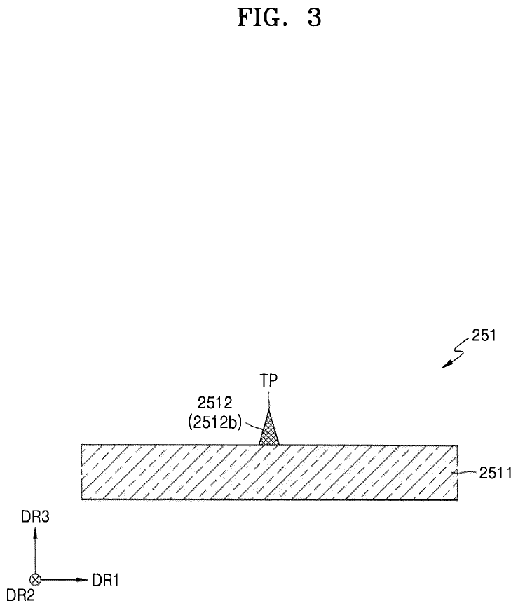

FIG. 2 is a plan view illustrating a mask frame, according to an embodiment. FIG. 3 is a cross-sectional view illustrating the mask frame, taken along line II-II′ of FIG. 2.

Referring to FIGS. 2 and 3, the first opening OP1 may be defined in the mask frame 251. In an embodiment, a plurality of first openings OP1 may be defined in the mask frame 251. The plurality of first openings OP1 may be spaced apart from each other (e.g., in a plan view). In an embodiment, the plurality of first openings OP1 may be arranged along one direction. For example, the first openings OP1 may be arranged along the first direction DR1 and/or the second direction DR2. The first opening OP1 of the mask frame 251 may define a cell area CA. As the plurality of first openings OP1 are provided, a plurality of cell areas CA may be defined to be spaced apart from each other (e.g., in a plan view). In an embodiment, the plurality of cell areas CA may be arranged along the first direction DR1 and/or the second direction DR2. In an embodiment, one cell area CA may correspond to one display panel 11 (see FIGS. 17 and 18) described below. In an embodiment, since the cell area CA may be defined by the first opening OP1, the shape and arrangement of the cell area CA may be substantially the same as the shape and arrangement of the first opening OP1.

In an embodiment, the mask frame 251 may include silicon (Si). In an embodiment, the mask frame 251 may be provided in the form of a silicon wafer. In an embodiment, the plurality of first openings OP1 of the mask frame 251 may be defined in the main body 2511 of the mask frame 251.

Although the mask frame 251 has a substantially circular shape (e.g., in a plan view) in FIG. 2, embodiments of the present disclosure are not necessarily limited thereto. The mask frame 251 may have any of various shapes such as a polygonal shape, an elliptical shape, or an irregular shape (e.g., in a plan view). Although each of the plurality of cell areas (or the plurality of first openings OP1) has a substantially square shape (e.g., in a plan view) in FIG. 2, embodiments of the present disclosure are not necessarily limited thereto. Each of the plurality of cell areas CA (or the plurality of first openings OP1) may have any of various shapes such as a polygonal shape, an elliptical shape, or an irregular shape (e.g., in a plan view), and shapes and/or sizes of the plurality of cell areas CA (or the plurality of first openings OP1) may be different from each other.

The mask frame 251 may include the protrusion 2512 on the main body 2511 (e.g., disposed directly thereon in the third direction DR3). In an embodiment, the mask frame 251 may include a plurality of protrusions 2512. The plurality of protrusions 2512 may be disposed between the plurality of cell areas CA (e.g., between the plurality of first openings OP1) in a plan view. In an embodiment, the plurality of protrusions 2512 may be disposed between a corner of one of the plurality of cell areas CA and a corner of another of the plurality of cell areas CA (e.g., in a plan view). In an embodiment, the protrusion 2512 may be disposed between a corner of the cell area CA and a corner of another cell area CA adjacent to the cell area CA in the first direction DR1. In an embodiment, the protrusion 2512 may be disposed between a corner of the cell area CA and a corner of another cell area CA adjacent to the cell area CA in the second direction DR2. In an embodiment, the protrusion 2512 may be disposed between a corner of the cell area CA and a corner of another cell area CA adjacent to the cell area CA in the first and second directions DR1 and DR2, that is, in a diagonal direction.

In an embodiment, the protrusion 2512 may include a first portion 2512a extending in the first direction DR1 and a second portion 2512b extending in the second direction DR2. In an embodiment, the protrusion 2512 may be provided in a cross shape or a+shape (e.g., in a plan view) including the first portion 2512a and the second portion 2512b. Although an embodiment where a width of the first portion 2512a of the protrusion 2512 in the second direction DR2 varies along the first direction DR1 and a width of the second portion 2512b in the first direction DR1 varies along the second direction DR2 is illustrated in FIG. 2, embodiments of the present disclosure are not necessarily limited thereto.

In an embodiment, a width of the protrusion 2512 in a cross-sectional view may vary. In an embodiment, a width of the protrusion 2512 may vary along one direction. In an embodiment, a width of the protrusion 2512 in the first direction DR1 or the second direction DR2 may be changed along a protruding direction (e.g., the third direction DR3) of the protrusion 2512. FIG. 3 illustrates an embodiment where a width of the protrusion 2512 in the first direction DR1 decreases along the third direction DR3. In an embodiment, the protrusion 2512 may have a tip TP at an end of the protruding direction (e.g., in the third direction DR3). In an embodiment, a width of the tip of the protrusion 2512 (e.g., a width in the first direction DR1) may be less than or equal to about 0.1 nanometers (nm).

In an embodiment, the protrusion 2512 may include the same material as the main body 2511. In an embodiment, the protrusion 2512 may include silicon (Si). In an embodiment, the protrusion 2512 may be integral with the main body 2511. In an embodiment, the protrusion 2512 may include a different material from the main body 2511. In an embodiment, the protrusion 2512 may include an oxide, such as silicon oxide (SiO₂) and/or a metal.

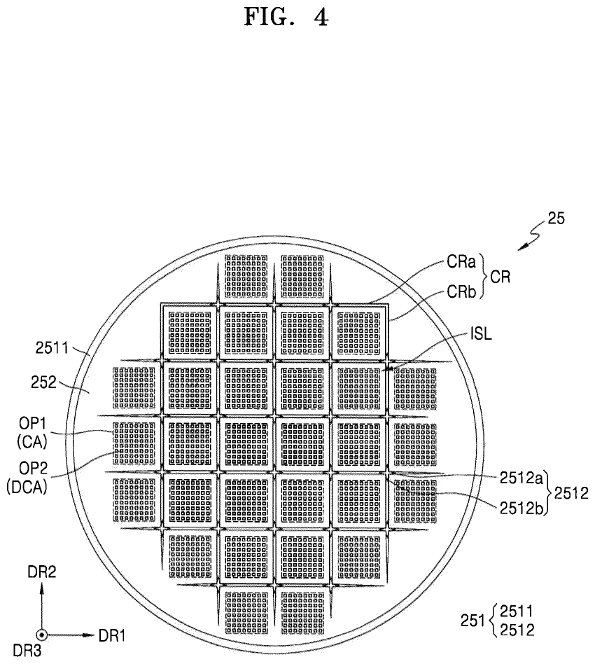

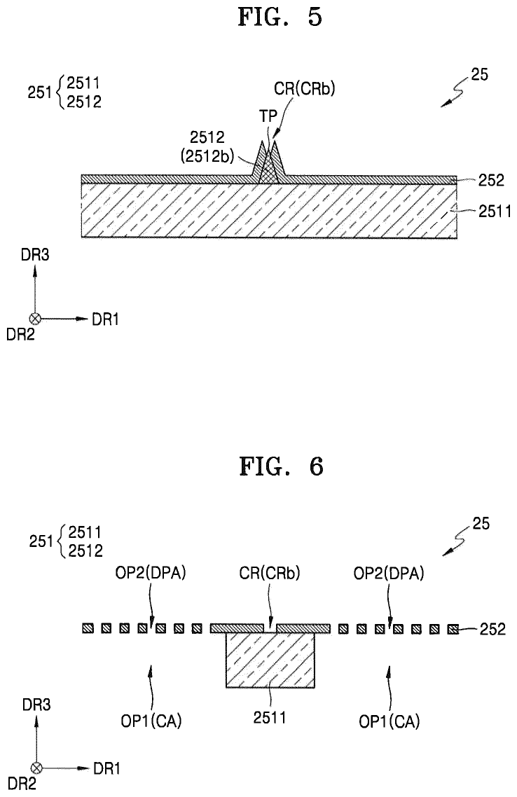

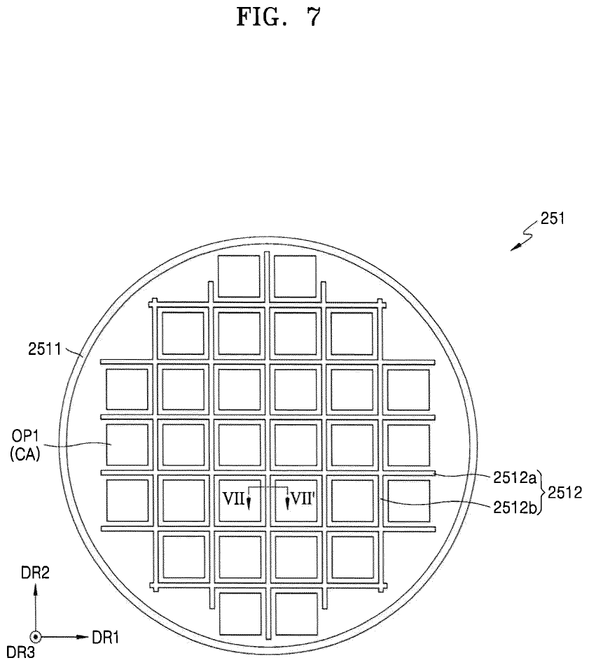

FIG. 4 is a plan view illustrating a deposition mask, according to an embodiment. FIG. 5 is a cross-sectional view illustrating a deposition mask, according to an embodiment. FIG. 6 is a cross-sectional view illustrating a deposition mask, according to an embodiment. The deposition mask 25 of FIGS. 4, 5, and 6 may include the mask frame 251 of FIGS. 2 and 3.

Referring to FIGS. 4, 5, and 6, the mask membrane 252 may be disposed on the mask frame 251 (e.g., disposed directly thereon in the third direction DR3). The mask membrane 252 may include a plurality of second openings OP2 overlapping (e.g., in the third direction DR3) the first opening OP1 or the cell area CA. The plurality of second openings OP2 may define a deposition area DPA of the deposition mask 25. The plurality of second openings OP2 may be provided in a shape defining the deposition area DPA. One first opening OP1 or one cell area CA may overlap the plurality of second openings OP2. In an embodiment, the mask membrane 252 may include silicon nitride (SiNₓ).

The mask membrane 252 may include a crack CR overlapping the protrusion 2512 of the mask frame 251. In an embodiment, the crack CR of the mask membrane 252 may be formed by fracture of the mask membrane 252 due to stress concentrated on a portion of the mask membrane 252 by the tip TP of the protrusion 2512 of the mask frame 251. Accordingly, the crack CR of the mask membrane 252 may overlap (e.g., in the third direction DR3) the protrusion 2512 of the mask frame 251, for example, the tip TP of the protrusion 2512.

Due to a shape of the protrusion 2512 including the first portion 2512a extending in the first direction DR1 and the second portion 2512b extending in the second direction DR2, the crack CR may include a first crack CRa extending in the first direction DR1 and a second crack CRb extending in the second direction DR2. In an embodiment, fracture of the mask membrane 252 caused by the first portion 2512a of the protrusion 2512 may extend along the first direction DR1, and thus, the first crack CRa may be formed. In an embodiment, fracture of the mask membrane 252 caused by the second portion 2512b of the protrusion 2512 may extend along the second direction DR2, and thus, the second crack CRb may be formed. In an embodiment, the first crack CRa may extend along the first direction DR1 between two cell areas CA or two first openings OP1 adjacent to each other in the second direction DR2. In an embodiment, the second crack CRb may extend along the second direction DR2 between two cell areas CA or two first openings OP1 adjacent to each other in the first direction DR1.

In an embodiment, a plurality of first cracks CRa and a plurality of second cracks CRb may be connected to each other to form a mesh structure (e.g., a mesh shape) in a plan view. The mesh structure may at least partially surround the plurality of cell areas CA and the plurality of first openings OP1 (e.g., in the plan view). The mask membrane 252 may include a plurality of islands ISL separated and spaced apart from each other (e.g., in the plan view) by the plurality of first cracks CRa and the plurality of second cracks CRb spatially connected to each other. For example, the mask membrane 252 may be separated into the plurality of islands ISL by the crack CR. In an embodiment, one island ISL may overlap one cell area CA or one first opening OP1 (e.g., in a plan view).

In an embodiment, an area between the plurality of cell areas CA may be an area (hereinafter, referred to as a non-deposition area) where deposition using the deposition mask 25 does not occur. When the crack CR of the mask membrane 252 as described above does not exist, fracture may occur in a random area of the mask membrane 252 due to stress applied to the mask membrane 252. The random area may include the cell area CA, and when fracture occurs in the cell area CA, a deposition defect may occur. Since the crack CR as described above is formed in the mask membrane 252, fracture and the crack CR may be concentrated on an area other than the cell area CA, and thus, fracture or the crack CR may not occur in the cell area CA. For example, the protrusion 2512 of the mask frame 251 may guide the crack CR of the mask membrane 252 to be formed in a non-deposition area, thereby preventing (or at least reducing) a defect of the deposition mask 25 due to fracture of the cell area CA. Stress applied to each island ISL when the mask membrane 252 is separated into the plurality of islands ISL by the crack CR may be less than stress applied to the entire mask membrane 252 when the entire mask membrane 252 is provided as a single body. Accordingly, warpage of the mask membrane 252 in each island ISL and further in each cell area CA may be prevented (or at least reduced) compared to a comparative embodiment in which the mask membrane 252 is provided as a single body without the crack CR.

Although an embodiment where the plurality of first cracks CRa and the plurality of second cracks CRb are spatially connected to each other to form one mesh structure is illustrated in FIG. 4, embodiments of the present disclosure are not necessarily limited thereto. In an embodiment, the plurality of first cracks CRa and the plurality of second cracks CRb may be formed in the mask membrane 252, some of the plurality of first cracks CRa and/or some of the plurality of second cracks CRb may not be connected to each other, and two or more mesh-type cracks CR separated from each other may be provided in the mask membrane 252.

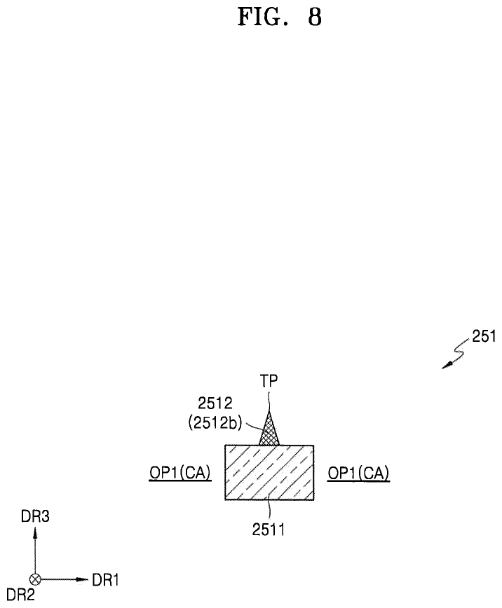

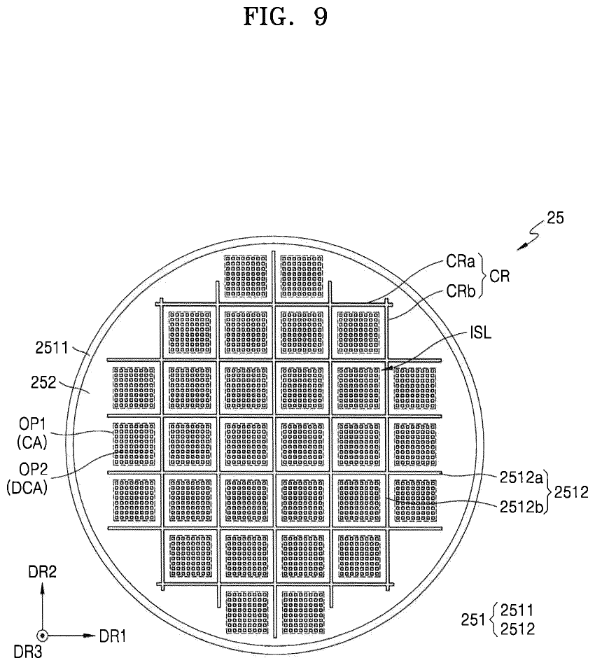

FIG. 7 is a plan view illustrating a mask frame, according to an embodiment. FIG. 8 is a schematic cross-sectional view illustrating the mask frame, taken along line VII-VII′ of FIG. 7.

Referring to FIGS. 7 and 8, in an embodiment the protrusion 2512 of the mask frame 251 may include the first portion 2512a extending in the first direction DR1 and the second portion 2512b extending in the second direction DR2. The first portion 2512a and the second portion 2512b of the protrusion 2512 may be connected to each other and may at least partially surround the plurality of cell areas CA or the plurality of first openings OP1 (e.g., in a plan view). For example, the protrusion 2512 may have a mesh structure (e.g., a mesh shape) including the first portion 2512a extending in the first direction DR1 and the second portion 2512b extending in the second direction DR2, and the mesh structure may at least partially surround the plurality of cell areas CA or the plurality of first openings OP1 (e.g., in a plan view). FIG. 7 illustrates an embodiment where the protrusion 2512 is integrally provided as one mesh structure. However, embodiments of the present disclosure are not necessarily limited thereto and other features of the mask frame 251 and the protrusion 2512 are the same as those described with reference to FIGS. 2 and 3.

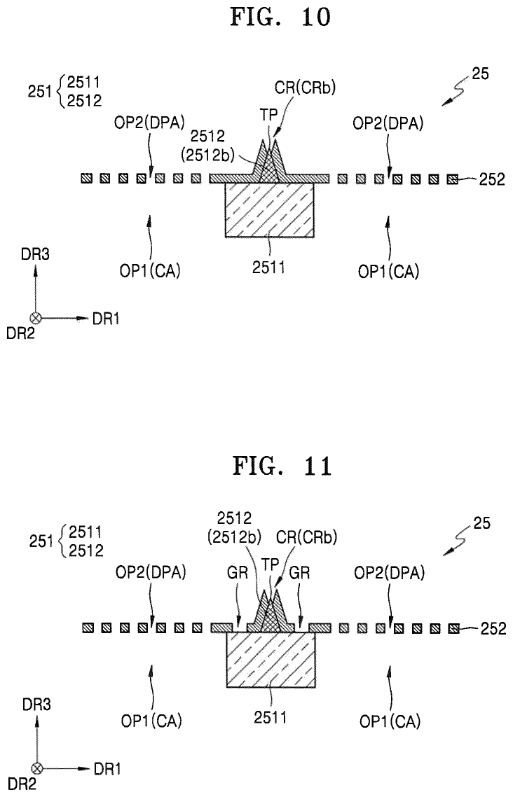

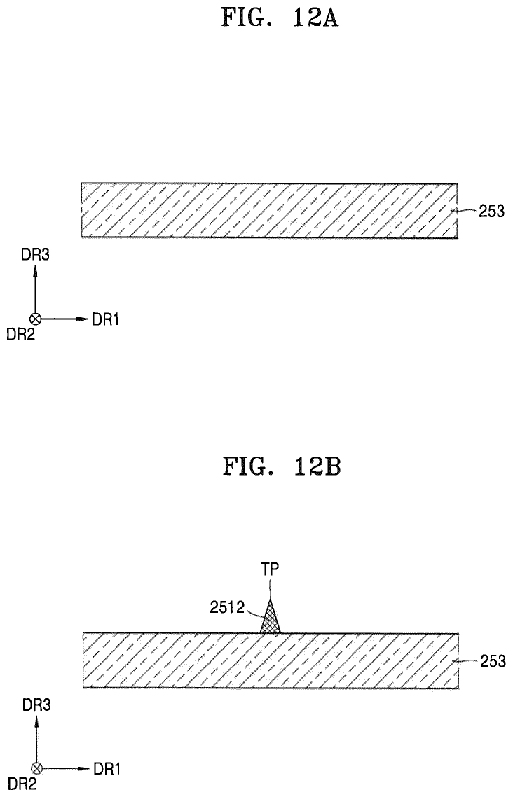

FIG. 9 is a plan view illustrating a deposition mask, according to an embodiment. FIG. 10 is a cross-sectional view illustrating a deposition mask, according to an embodiment. The deposition mask 25 of FIGS. 9 and 10 may include the mask frame 251 of FIGS. 7 and 8.

Referring to FIGS. 9 and 10, in an embodiment the crack CR of the mask membrane 252 may entirely overlap the protrusion 2512 of the mask frame 251. In the present embodiment, the protrusion 2512 of the mask frame 251 may be provided in a mesh structure at least partially surrounding the plurality of cell areas CA or the plurality of first openings OP1 (e.g., in a plan view). The mask membrane 252 may be guided to be fractured along the mesh structure of the protrusion 2512, and thus, the crack CR of the mask membrane 252 may entirely extend along the protrusion 2512.

Compared to an embodiment shown in FIG. 4, in an embodiment of FIG. 4, the protrusions 2512 may be spaced apart from each other and disposed at multiple positions, fracture of the mask membrane 252 may occur at a position where each protrusion 2512 is disposed, and the fracture may extend along the first direction DR1 or the second direction DR2. For example, the mask membrane 252 may be additionally (or continuously) split along initial fracture formed by the protrusion 2512. The protrusion 2512 may include the first portion 2512a and the second portion 2512b to guide the additional fracture in the first direction DR1 or the second direction DR2.

In contrast, in the embodiment of FIG. 9, the protrusion 2512 itself may be provided in a mesh shape, and initial fracture of the mask membrane 252 may be formed in a mesh shape. In an embodiment, the initial fracture may not occur exactly simultaneously in all areas overlapping the protrusion 2512. The protrusion 2512 may include the first portion 2512a and the second portion 2512b to guide the initial fracture to be formed along the first direction DR1 or the second direction DR2 between the plurality of cell areas CA.

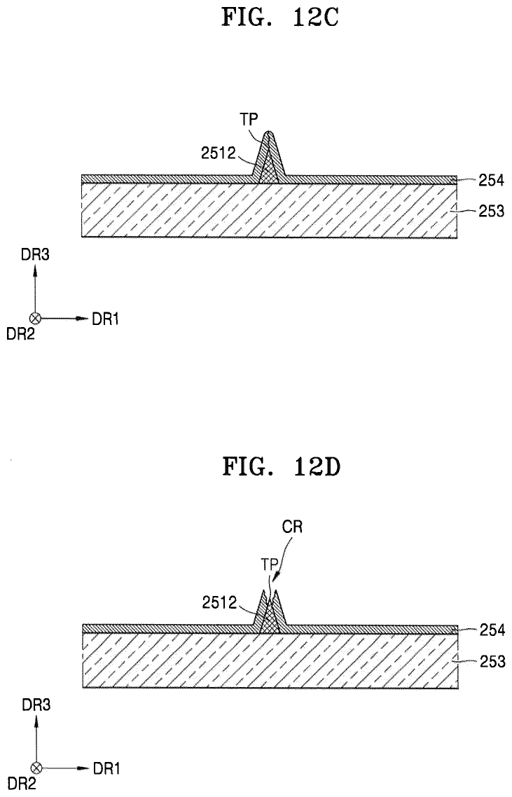

FIG. 11 is a cross-sectional view illustrating a deposition mask, according to an embodiment.

Referring to FIG. 11, a groove GR disposed between the cell area CA (or the first opening OP1) and the protrusion 2512 (e.g., in a plan view) may be defined in the mask membrane 252. The groove GR may be disposed between the deposition area DPA (e.g., the second opening OP2) of the mask membrane 252 and the crack CR. The groove GR may separate a part of the mask membrane 252 disposed on the protrusion 2512 from a part of the mask membrane 252 where the deposition area DPA is defined. Accordingly, warpage that may occur in the part of the mask membrane 252 where the deposition area DPA is defined may be prevented (or at least reduced). The groove GR of FIG. 11 may be combined with an embodiment described with reference to FIGS. 2 to 6 or an embodiment described with reference to FIGS. 7 to 10.

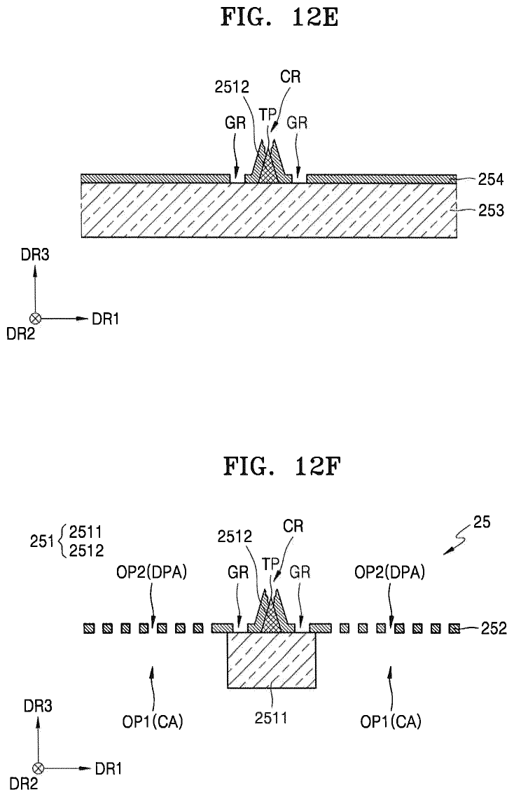

FIGS. 12A to 12F are cross-sectional views illustrating processes of a method of manufacturing a deposition mask, according to an embodiment. A method of manufacturing a deposition mask will be described based on the cross-sectional views of FIGS. 12A to 12F, and planar shapes in processes of the method of manufacturing a deposition mask are the same as those described with reference to FIGS. 2 to 6 or 7 to 10.

Referring to FIG. 12A, a mask frame substrate 253 may be prepared. In an embodiment, the mask frame substrate 253 may include silicon (Si). In an embodiment, the mask frame substrate 253 may be provided in the form of a silicon wafer.

Referring to FIG. 12B, the protrusion 2512 may be formed on the mask frame substrate 253 (e.g., formed directly thereon in the third direction DR3). The planar shape and/or arrangement of the protrusion 2512 is the same as that described with reference to FIG. 2 or 7.

In an embodiment, the protrusion 2512 may include the same material (e.g., silicon (Si)) as the mask frame substrate 253. In an embodiment, the protrusion 2512 may be formed by etching the mask frame substrate 253. For example, a process of forming the protrusion 2512 may include a process of etching the mask frame substrate 253.

In an embodiment, the protrusion 2512 may include a material (e.g., an oxide or a metal) different from that of the mask frame substrate 253. In an embodiment, the protrusion 2512 may be patterned on the mask frame substrate 253.

Referring to FIG. 12C, a mask membrane substrate 254 may be disposed on the mask frame substrate 253 and the protrusion 2512. The mask membrane substrate 254 may entirely cover the mask frame substrate 253 and the protrusion 2512 (e.g., in a plan view). FIG. 12C illustrates fracture (e.g., initial fracture) formed in the mask frame substrate 253. The fracture may overlap the protrusion 2512, for example, the tip TP of the protrusion 2512 (e.g., in the third direction DR3).

Referring to FIG. 12D, the crack CR may occur in the mask frame substrate 253 at a portion overlapping the protrusion 2512 (e.g., in the third direction DR3), such as due to the stress caused by the protrusion 2512 on the mask frame substrate 253. The crack CR may overlap the protrusion 2512, for example, the tip TP of the protrusion 2512. The protrusion 2512 may guide stress to be concentrated on a specific portion of the mask membrane substrate 254 through the tip TP to form the crack CR. The planar shapes and/or arrangements of the protrusion 2512 and the crack CR are the same as those described with reference to FIG. 4 or 9.

Referring to FIG. 12E, in an embodiment the groove GR may be formed in the mask membrane substrate 254. The groove GR may be disposed adjacent to the protrusion 2512 or the crack CR (e.g., in a plan view). A process illustrated in FIG. 12E may be performed or may be omitted. In an embodiment in which the process illustrated in FIG. 12E is performed, an embodiment described with reference to FIG. 11 may be implemented. In an embodiment in which the process illustrated in FIG. 12E is omitted, an embodiment described with reference to FIGS. 2 to 6 or 7 to 10 may be implemented.

Referring to FIGS. 12E and 12F, the mask frame 251 may be formed by forming the first opening OP1 in the mask frame substrate 253, and the mask membrane 252 may be formed by forming the second opening OP2 in the mask membrane substrate 254. In an embodiment, the first opening OP1 may be formed by etching the mask frame substrate 253. In an embodiment, the second opening OP2 may be formed by etching the mask membrane substrate 254. The first opening OP1 may define the cell area CA. The second opening OP2 may define the deposition area DPA. The protrusion 2512 and the crack CR may be disposed between the first openings OP1 and the cell areas CA (e.g., in a plan view). Due to the protrusion 2512, the crack CR may be disposed between the cell areas CA and the first openings OP1. In an embodiment, the arrangement of the cell area CA and the arrangement of the deposition area DPA may be pre-determined, and the protrusion 2512 may be disposed to avoid the cell area CA or the deposition area DPA. Accordingly, the crack CR may be formed to avoid (e.g., not be disposed in) the cell area CA or the deposition area DPA.

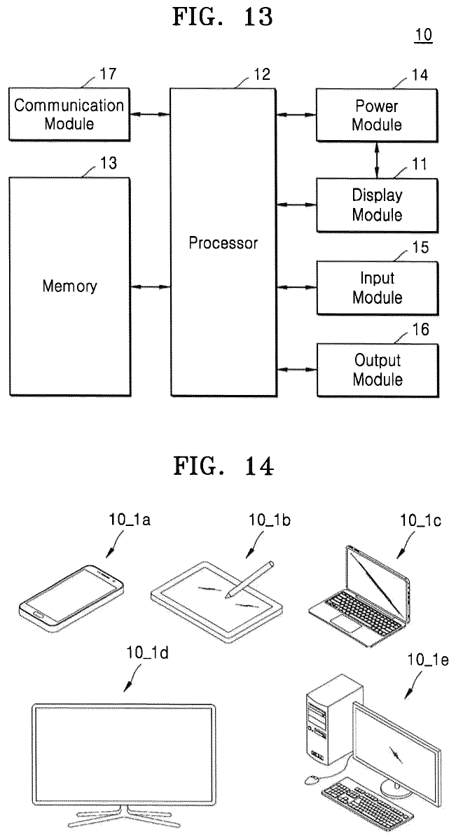

FIG. 13 is a block diagram illustrating an electronic device, according to an embodiment.

Referring to FIG. 13, an electronic device 10 may include a display panel 11, a processor 12, a memory 13, and a power module 14. In an embodiment, the display panel 11 may be manufactured through the apparatus 2 for manufacturing a display panel described with reference to FIG. 1.

The processor 12 may include at least one of a central processing unit (CPU), an application processor (AP), a graphics processing unit (GPU), a communication processor (CP), an image signal processor (ISP), and a controller. In an embodiment, the processor 12 may be divided into two or more from a functional or structural point of view. For example, the processor 12 may include a main processor as a first driving chip including a CPU, and an auxiliary processor as a second driving chip including a controller that receives an image signal from the main processor and processes the image signal to meet interface specifications of the display panel 11.

In an embodiment, the memory 13 may include at least one of a nonvolatile memory and a volatile memory. The memory 13 may store data information necessary for an operation of the processor 12 or the display panel 11. When the processor 12 executes an application stored in the memory 13, an image data signal and/or an input control signal may be transmitted to the display panel 11, and the display panel 11 may process the received signal and may output image information through a display screen. In an embodiment, the power module 14 may include a power supply module, such as a power adaptor or a battery device, and a power conversion module configured to convert power supplied by the power supply module and generate power necessary for an operation of the electronic device 10. Power conversion by the power conversion module may include, but is not necessarily limited to, direct current (DC)-DC conversion, alternating current (AC)-DC conversion, and DC-AC conversion.

The electronic device 10 may further include an input module 15, a non-image output module 16, and/or a communication module 17.

The input module 15 may provide input information to the processor 12 and/or the display panel 11. The input module 15 may include not only a physical button, a keyboard, and a microphone but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors such as a blood pressure sensor, a blood sugar sensor, an electrocardiogram sensor, and a heart rate sensor.

The non-image output module 16 may receive information other than an image received from the processor 12 and may provide the information to a user. Examples of the non-image output module 16 may include a sound module, a haptic module, and a light-emitting module, and may also include other functionally intrinsic modules (e.g., a cooling module of a refrigerator) of an electronic device.

The communication module 17 is a module for transmitting/receiving information between the electronic device 10 and an external device, and may include a receiver and a transmitter. The communication module 17 may include various wireless communication modules, such as a mobile communication module, a Wi-Fi module, and a Bluetooth module, or various wired communication modules.

At least one of the components of the electronic device 10 described above may be included in a display apparatus. Also, some of individual modules functionally included in one module may be included in the display apparatus and the others may be provided separately from the display apparatus. For example, the display apparatus may include the display panel 11, and the processor 12, the memory 13, and the power module 14 may be provided as other devices in the electronic device 10, rather than the display apparatus. In another example, the power module 14 may be provided in the display apparatus, and may supply power to the processor 12 and the memory 13 provided in the electronic device 10, rather than the display apparatus. However, embodiments of the disclosure are not necessarily limited thereto.

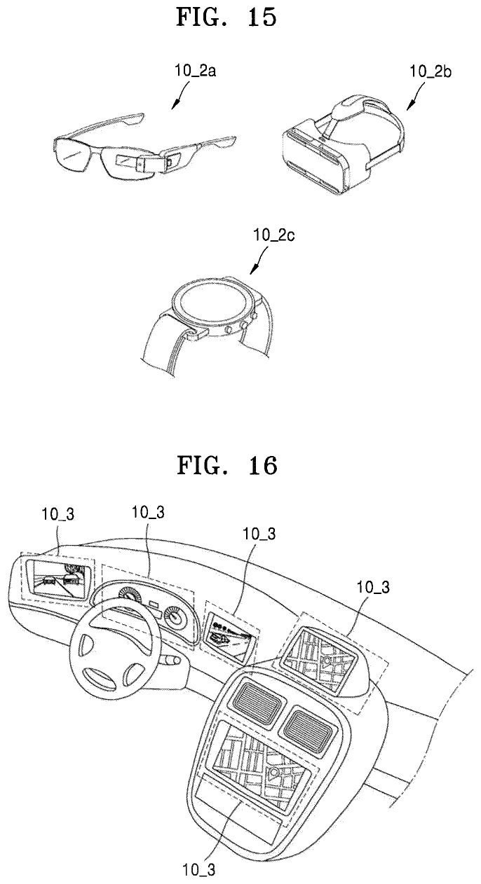

FIGS. 14 to 16 are schematic views illustrating an electronic device, according to various embodiments. FIGS. 14 to 16 illustrate examples of various electronic devices to which a display apparatus is applied, according to embodiments.

FIG. 14 illustrates a smartphone 10_1a, a tablet PC 10_1b, a laptop computer 10_1c, a TV 10_1d, and a monitor 10_1e for a desk as examples of an electronic device.

The smartphone 10_1a may include an input module, such as a touch sensor, and a communication module, in addition to a display panel. The smartphone 10_1a may process information received through the communication module or other input modules and may display the information through the display panel of the display apparatus.

Each of the table PC 10_1b, the laptop computer 10_1c, the TV 10_1d, and the monitor 10_1e for a desk may also include a display panel and an input module, like the smartphone 10_1a, and may further include a communication module when necessary.

FIG. 15 illustrates a case where an electronic device including a display panel is applied to a wearable electronic device. Examples of the wearable electronic device may include smart glasses 10_2a, a head-mounted display 10_2b, and a smart watch 10_2c.

The smart glasses 10_2a and the head-mounted display 10_2b may include a display panel that emits a display image and a reflector that reflects the emitted display screen and provides the display screen to a user's eyes, thereby providing a screen of virtual reality or augmented reality to the user.

The smart watch 10_2c may include a biometric sensor as an input device, and may provide biometric information recognized through the biometric sensor to the user through a display panel.

FIG. 16 illustrates a case where an electronic device including a display panel is applied to a vehicle. For example, an electronic device 10_3 may be applied to a dashboard or a center fascia of a vehicle, or may be applied to a center information display (CID) disposed on a dashboard of a vehicle or a room mirror display that replaces a side-view mirror.

In an embodiment, examples of an electronic device to which a display apparatus according to embodiments is applied may include not only devices that mainly display screens, such as an advertisement board, an electronic display board, and a game console, but also various home appliances that display information through a display panel, such as a refrigerator, a washing machine, a drier, an air conditioner, and a robot cleaner. Also, when a display panel has a function of transmitting light, the display panel may be applied to an electronic device such as a smart window or a transparent display apparatus that displays both a background and a display image. Types of an electronic device according to an embodiment are not limited to the examples described above, and various other small-sized, medium-sized or large-sized electronic devices may also be provided.

FIG. 17 is a schematic plan view illustrating an electronic device, according to an embodiment. FIG. 18 is a cross-sectional view illustrating a display panel, according to an embodiment.

Although the electronic device 10 is shown as being a smartphone in FIG. 17, embodiments of the present disclosure are not necessarily limited thereto. The electronic device 10 may include the display panel 11 and a housing 19. In an embodiment, the display panel 11 may be accommodated in the housing 19. The housing 19 is not implemented only as a type illustrated in FIG. 17, and may be the housing 19 referred to in the specification without being necessarily limited in type or shape as long as the housing 19 provides a space in which the display panel 11 may be accommodated.

Referring to FIGS. 17 and 18, a display area DA and a peripheral area PA outside the display area DA (e.g., in a plan view) may be defined on a substrate 91 of the display panel 11. In the display area DA, a light-emitting element 98 may be disposed, and in a non-display area, a power supply wiring may be disposed.

In the display area DA, a plurality of deposition material patterns may be disposed. Although the display panel 11 and the display area DA have substantially quadrangular shapes (e.g., in a plan view) in FIG. 17, embodiments of the present disclosure are not necessarily limited thereto. The display panel 11 and/or the display area DA may have another shape, for example, an irregular shape, a polygonal shape, etc. (e.g., in a plan view).

In an embodiment, the display panel 11 may include the substrate 91, a thin-film transistor TFT disposed on the substrate 91, and the light-emitting element 98 disposed on the thin-film transistor TFT. The light-emitting element 98 may be electrically connected to a thin-film transistor TFT.

In an embodiment, the substrate 91 may include a plastic material or a metal material. In an embodiment, the substrate 91 may include polyimide (PI). The thin-film transistor TFT may be disposed on the substrate 91 (e.g., in the third direction DR3), a via layer 97 may be disposed to cover the thin-film transistor TFT, and the light-emitting element 98 may be disposed on the via layer 97 (e.g., in the third direction DR3).

In an embodiment, a buffer layer 92 including an inorganic insulating material may be further disposed on a top surface of the substrate 91 (e.g., disposed directly thereon in the third direction DR3). In an embodiment, the buffer layer 92 may include silicon oxide (SiO₂), silicon nitride (SiNₓ), and/or silicon oxynitride (SiON).

An active layer 93 may be disposed in a certain pattern on the buffer layer 92 (e.g., disposed directly thereon in the third direction DR3), and the active layer 93 may be covered by a gate insulating layer 94. The active layer 93 may have a source region 93-1 and a drain region 93-3, and may have a channel region 93-2 between the source region 93-1 and the drain region 93-3.

The active layer 93 may be formed of various materials. In an embodiment, the active layer 93 may include an inorganic semiconductor material such as amorphous silicon or crystalline silicon. In an embodiment, the active layer 93 may include an oxide semiconductor. In an embodiment, the active layer 93 may include an organic semiconductor material.

In an embodiment, the active layer 93 may be formed by forming an amorphous silicon film on the buffer layer 92, crystallizing the amorphous silicon film to form a polycrystalline silicon film, and patterning the polycrystalline silicon film. In the active layer 93, the source region 93-1 and the drain region 93-3 may be doped with impurities.

A gate electrode 95 corresponding to the active layer 93 and an interlayer insulating layer 96 covering the gate electrode 95 may be disposed on a top surface of the gate insulating layer 94. In an embodiment, after a contact hole H1 is formed in the interlayer insulating layer 96 and the gate insulating layer 94, a source electrode 97-1 and a drain electrode 97-2 may be disposed on the interlayer insulating layer 96 to respectively directly contact the source region 93-1 and the drain region 93-3.

The via layer 97 may be disposed on (e.g., disposed directly thereon) the thin-film transistor TFT, and a pixel electrode 98-1 of the light-emitting element 98 may be disposed on the via layer 97 (e.g., disposed directly thereon in the third direction DR3). In an embodiment, the pixel electrode 98-1 may directly contact the drain electrode 97-2 of the thin-film transistor TFT through a via hole H2 formed in the via layer 97. The via layer 97 may include an inorganic material and/or an organic material and may have a single or multi-layer structure. The via layer 97 may be formed as a planarization film so that a top surface thereof is flat regardless of a curvature of a lower film, or may be formed to be curved along a curvature of a lower film.

After the pixel electrode 98-1 is disposed on the via layer 97, a pixel-defining film 99 may be formed to cover the pixel electrode 98-1 and the via layer 97, and the pixel-defining film 99 may have an opening exposing a part of the pixel electrode 98-1. For example, in an embodiment the pixel-defining film 99 may cover lateral edges of the pixel electrode 98-1 and may expose a central portion of the pixel electrode 98-1.

An intermediate layer 98-2 and a counter electrode 98-3 may be disposed on the pixel electrode 98-1. The counter electrode 98-3 may be disposed on the intermediate layer 98-2 and the pixel-defining film 99. In an embodiment, the counter electrode 98-3 may be disposed on an entire surface of the substrate 91.

The intermediate layer 98-2 may include an emission layer. In an embodiment, the intermediate layer 98-2 may include the emission layer, and may further include at least one of a hole injection layer, a hole transport layer, an electron transport layer, and an electron injection layer. However, embodiments of the present disclosure are not necessarily limited thereto, and the intermediate layer 98-2 may include the emission layer and may further include various other functional layers.

The pixel electrode 98-1 and the counter electrode 98-3 may be insulated from each other by the intermediate layer 98-2. Voltages of different polarities may be applied to the intermediate layer 98-2 by the pixel electrode 98-1 and the counter electrode 98-3 so that the emission layer included in the intermediate layer 98-2 emits light.

In an embodiment, a plurality of intermediate layers 98-2 may be provided, and the plurality of intermediate layers 98-2 may form the display area DA. In this embodiment, the plurality of intermediate layers 98-2 may be spaced apart from each other in the display area DA (e.g., in a plan view). In an embodiment, a pattern in which the plurality of intermediate layers 98-2 are disposed may be determined by a deposition area of a deposition mask described above.

A thin-film encapsulation layer E may include a plurality of inorganic layers or may include an inorganic layer and an organic layer. In an embodiment, the organic layer of the thin-film encapsulation layer E may be formed of a polymer, and may have a single or multi-layer structure including any one of polyethylene terephthalate, polyimide, polycarbonate, epoxy, polyethylene, and polyacrylate. The inorganic layer of the thin-film encapsulation layer E may have a single or multi-layer structure including a metal oxide or a metal nitride. For example, in an embodiment the inorganic layer may include any one of silicon oxide (SiO₂), silicon nitride (SiNₓ), silicon oxynitride (SiON), aluminum oxide (Al₂O₃), and titanium oxide (TiO₂). An uppermost layer exposed to the outside among layers of the thin-film encapsulation layer E may be an inorganic layer to prevent moisture penetration into the light-emitting element.

The thin-film encapsulation layer E may include at least one sandwich structure in which at least one organic layer is inserted between at least two inorganic layers. In an embodiment, the thin-film encapsulation layer E may include at least one sandwich structure in which at least one inorganic layer is inserted between at least two organic layers. In an embodiment, the thin-film encapsulation layer E may include a sandwich structure in which at least one organic layer is inserted between at least two inorganic layers and a sandwich structure in which at least one inorganic layer is inserted between at least two organic layers.

According to an embodiment, there is provided a deposition mask including a mask membrane with a crack formed between cell areas where openings of the mask membrane defining a deposition area are disposed. The crack may be guided to be solely formed between the cell areas by a protrusion of a mask frame of the deposition mask. As the crack is intentionally formed in an area other than the cell area, a crack may be prevented (or at least reduced) from occurring in the mask membrane in the cell area. Also, stress applied to the mask membrane in the cell area may be reduced. According to an embodiment, there is provided a method of manufacturing a deposition mask as described above. According to an embodiment, there is provided an apparatus for manufacturing a display panel including a deposition mask as described above.

It should be understood that embodiments described herein should be considered in a descriptive sense only and not for purposes of limitation. Descriptions of features or aspects within each embodiment should typically be considered as available for other similar features or aspects in other embodiments. While one or more non-limiting embodiments have been described with reference to the figures, it will be understood by one of ordinary skill in the art that various changes in form and details may be made therein without departing from the spirit and scope of the present disclosure.

What is claimed is:

1. A deposition mask comprising:
a mask frame comprising a plurality of cell areas arranged to be spaced apart from each other in a plan view and a protrusion disposed between the plurality of cell areas in the plan view; and
a mask membrane disposed on the mask frame and comprising a crack overlapping the protrusion.

2. The deposition mask of claim 1, wherein the protrusion comprises a first portion extending in a first direction and a second portion extending in a second direction intersecting the first direction.

3. The deposition mask of claim 1, wherein the protrusion is disposed between a corner of one of the plurality of cell areas and a corner of another of the plurality of cell areas in the plan view.

4. The deposition mask of claim 1, wherein the protrusion is provided in a mesh shape at least partially surrounding the plurality of cell areas in the plan view.

5. The deposition mask of claim 1, wherein the protrusion has a width that decreases in a protruding direction in a cross-sectional view.

6. The deposition mask of claim 5, wherein a width of a tip of the protrusion is less than or equal to about 0.1 nanometers.

7. The deposition mask of claim 1, wherein the crack of the mask membrane comprises a first crack extending in a first direction and a second crack extending in a second direction intersecting the first direction and is defined in a mesh shape at least partially surrounding the plurality of cell areas in the plan view.

8. The deposition mask of claim 7, wherein the mask membrane is separated into a plurality of islands in the plan view by the crack.

9. The deposition mask of claim 1, wherein the mask membrane includes a groove disposed between the protrusion and the plurality of cell areas of the mask frame in the plan view.

10. The deposition mask of claim 1, wherein
the mask frame includes a plurality of first openings corresponding to the plurality of cell areas; and
the mask membrane includes a plurality of second openings overlapping the plurality of first openings and defining a deposition area.

11. A method of manufacturing a deposition mask, the method comprising:
forming on a mask frame substrate comprising a plurality of cell areas arranged to be spaced apart from each other in a plan view, a protrusion between the plurality of cell areas in the plan view; and
disposing a mask membrane substrate on the mask frame substrate to form a crack overlapping the protrusion.

12. The method of claim 11, wherein the protrusion is disposed between a corner of one of the plurality of cell areas and a corner of another of the plurality of cell areas in the plan view.

13. The method of claim 11, wherein the protrusion is provided in a mesh shape at least partially surrounding the plurality of cell areas in the plan view.

14. The method of claim 11, wherein, in a cross-sectional view, the protrusion has a width that decreases in a protruding direction, and the crack overlaps a tip of the protrusion.

15. The method of claim 11, wherein the forming of the protrusion comprises etching the mask frame substrate.

16. The method of claim 11, wherein the protrusion comprises a different material from the mask frame substrate.

17. The method of claim 11, wherein the crack comprises a first crack extending in a first direction and a second crack extending in a second direction intersecting the first direction, the crack is defined in a mesh shape at least partially surrounding the plurality of cell areas in the plan view, and the mask membrane substrate is separated into a plurality of islands in the plan view by the crack.

18. The method of claim 11, further comprising forming, in the mask membrane substrate, a groove disposed between the crack and the plurality of cell areas in the plan view.

19. The method of claim 11, further comprising:
forming a plurality of first openings corresponding to the plurality of cell areas in the mask frame substrate; and
forming a plurality of second openings overlapping the plurality of first openings and defining a deposition area in the mask membrane substrate.

20. An apparatus for manufacturing a display panel, the apparatus
comprising: a chamber;
a deposition mask disposed in the chamber; and
a deposition source disposed in the chamber to face the deposition mask,
wherein the deposition mask comprises:
a mask frame comprising a plurality of cell areas arranged to be spaced apart from each other in a plan view and a protrusion disposed between the plurality of cell areas in the plan view; and
a mask membrane disposed on the mask frame and comprising a crack overlapping the protrusion.
